(19) United States
(12) Patent Application Publication
(10) Pub. No.: US 2020/0267826 A1
(43) Pub. Date: Aug. 20, 2020

(54) SUBSTRATE PROCESSING APPARATUS

(71) Applicant: Tokyo Electron Limited, Tokyo (JP)

(72) Inventors: Daisuke KAWADA, Miyagi (JP); Koichi KAZAMA, Miyagi (JP); Dong suk KIM, Miyagi (JP); Namho YUN, Gyeonggi-do (KR); Jisoo SUH, Gyeonggi-do (KR)

(21) Appl. No.: 16/793,080

(22) Filed: Feb. 18, 2020

(30) Foreign Application Priority Data
Feb. 19, 2019 (JP) 2019-027732

(51) Int. Cl. H05H 1/46; H01J 37/32

(52) U.S. Cl. CPC H05H 1/46; H01J 37/321; H05H 2001/4645; H01J 37/3244; H01J 37/32633

(57) ABSTRACT

There is provision of a substrate processing apparatus including a processing vessel, a radio frequency power supply configured to supply radio frequency (RF) current, and a member connected to the processing vessel electrically. The member is configured such that a surface area per unit volume of a first region of the member corresponding to a particular structure of the processing vessel differs from a surface area per unit volume of a second region of the member other than the first region, in order to adjust impedance of the member.

### CROSS-REFERENCE TO RELATED APPLICATIONS

This patent application is based upon and claims priority to Japanese Patent Application No. 2019-027732 filed on Feb. 19, 2019, the entire contents of which are incorporated herein by reference.

### TECHNICAL FIELD

The present disclosure relates to a substrate processing apparatus.

### BACKGROUND

In a plasma processing apparatus, an annular baffle plate having multiple through-holes is provided between a side wall of a processing vessel and a stage. For example, Patent Document 1 proposes a method of forming an anodized aluminum layer on a surface of a baffle plate formed of aluminum, and thermal spraying an yttria film on the anodized aluminum layer, to improve withstand voltage of the baffle plate exposed to a plasma.

### CITATION LIST

### Patent Document

[Patent Document 1] Japanese Laid-open Patent Application Publication No. 2016-028379

### SUMMARY

The present disclosure provides a substrate processing apparatus capable of adjusting impedance in a member forming a ground plane with respect to radio frequency electric power.

According to one aspect of the present disclosure, there is provision of a substrate processing apparatus including a processing vessel, a radio frequency power supply configured to supply radio frequency (RF) current, and a member connected to the processing vessel electrically. The member is configured such that a surface area per unit volume of a first region of the member corresponding to a particular structure of the processing vessel differs from a surface area per unit volume of a second region of the member other than the first region, in order to adjust impedance of the member.

### BRIEF DESCRIPTION OF THE DRAWINGS

FIG. 1 is a cross-sectional view illustrating an example of a substrate processing apparatus according to an embodiment;

FIGS. 2A and 2B are enlarged views each illustrating an example of a baffle plate, a shutter, and the surroundings thereof according to the embodiment;

FIG. 3 is a perspective view illustrating an example of the baffle plate according to the embodiment; and

FIG. 4 is a cross-sectional view illustrating an enlarged through-hole provided on the baffle plate according to the embodiment.

### DETAILED DESCRIPTION OF EMBODIMENTS

Hereinafter, an embodiment for carrying out the present invention will be described with reference to the drawings. With respect to the same members, the same reference symbols are attached, and duplicate descriptions are omitted.

[Overall Configuration of Substrate Processing Apparatus]

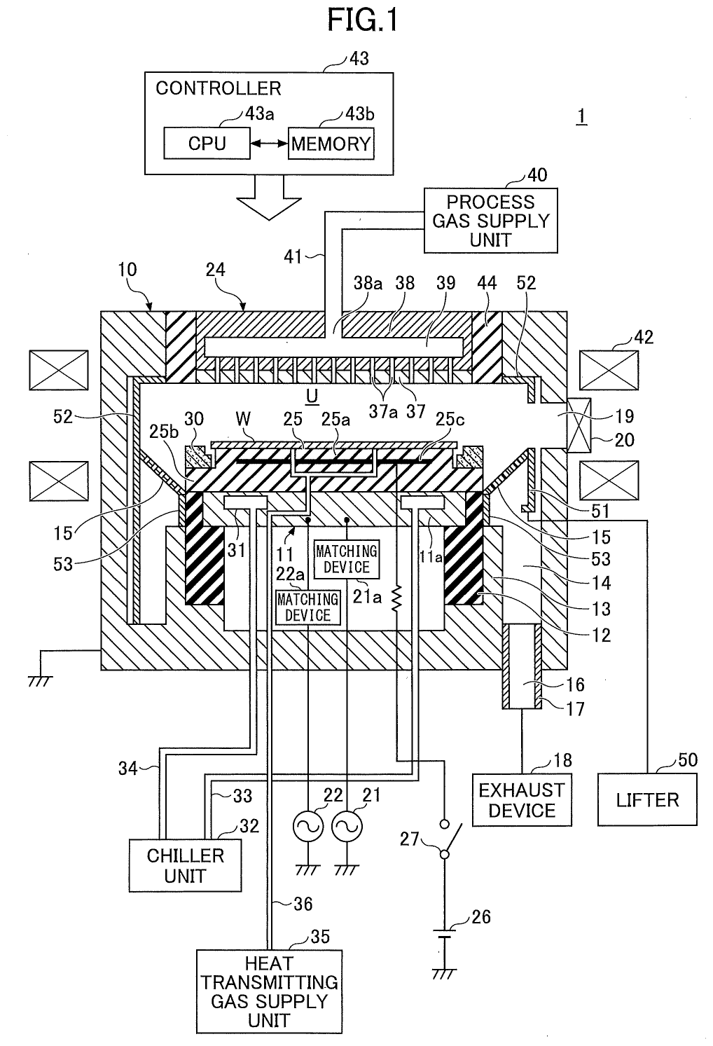

First, the configuration of the substrate processing apparatus 1 according to an embodiment will be described with reference to FIG. 1. FIG. 1 is a cross-sectional diagram illustrating an example of a substrate processing apparatus 1 according to an embodiment. In the present embodiment, a substrate processing apparatus 1 of the RIE (Reactive Ion Etching) type will be described with reference to an example.

The substrate processing apparatus 1 includes a cylindrical processing vessel 10 made of metal such as aluminum or stainless steel, the interior of which is a processing space U in which plasma processing, such as plasma etching or plasma CVD, is performed. The processing vessel 10 is grounded.

A disk-shaped stage 11 for placing a wafer W is disposed in the processing vessel 10. The stage 11 includes a base member 11a and an electrostatic chuck 25. The base member 11a is made of aluminum for example, and is supported, via an insulating cylindrical support member 12, by a cylindrical support 13 extending upwardly from the bottom of the processing vessel 10 in a vertical direction.

The electrostatic chuck 25 is disposed on the base member 11a. The electrostatic chuck 25 includes a disc-shaped central member 25a on which the wafer W is placed and an annular peripheral member 25b at the outside of the central member 25a. A height of the central member 25a is higher than a height of the peripheral member 25b.

The central member 25a is formed by sandwiching an electrode 25c made of a conductive film between a pair of dielectric films. A direct current (DC) power supply 26 is electrically connected to the electrode 25c via a switch 27. The electrostatic chuck 25 produces an electrostatic force due to DC voltage applied to the electrode 25c from the DC power supply 26, which attracts and holds the wafer W. An edge ring 30 (also referred to as a focus ring) is disposed on an upper surface of the peripheral member 25b, which annularly surrounds the substrate. The edge ring 30 is made of, for example, silicon.

Inside the stage 11, for example, an annular refrigerant chamber 31 extending in a circumferential direction is provided. A heating medium at a predetermined temperature, such as cooling water, is supplied to the refrigerant chamber 31 from a chiller unit 32 through pipes 33 and 34. As the heating medium circulates through the refrigerant chamber 31, a temperature of the wafer W on the electrostatic chuck 25 is controlled by the heating medium.

A heat transmitting gas supply unit 35 is connected to the electrostatic chuck 25 via a gas supply line 36. The heat transmitting gas supply unit 35 uses the gas supply line 36 to supply heat transmitting gas to a gap between an upper surface of the central member 25a of the electrostatic chuck 25 and a back surface of the wafer W. As the heat transmitting gas, a gas having heat conductivity, for example, He gas or the like, is preferably used.

A first radio frequency power supply 21 for plasma generation and RIE is electrically connected to stage 11 via a matching device 21a. The first radio frequency power supply 21 applies power at a first radio frequency, e.g., 40 MHz, to the stage 11.

A second radio frequency power supply 22 for attracting ions is electrically connected to the stage 11 via a matching device 22a. The second radio frequency power supply 22 applies power to the stage 11 at a second radio frequency, e.g., 3 MHz, which is lower than the first radio frequency.

A gas showerhead 24 is provided at a ceiling of the processing vessel 10. As the first radio frequency power and/or the second radio frequency power is supplied, a radio frequency electric field is generated between the gas showerhead 24 (top electrode) and the stage 11 (bottom electrode). The predetermined gas output from a process gas supply unit 40 is supplied from the gas showerhead 24 in a shower-like manner, and is formed into a plasma by the radio frequency electric field in a processing space U.

A deposition shield 52 is removably provided at an inner wall of the processing vessel 10. The deposition shield 52 prevents reaction products generated during plasma processing from adhering to the inner wall of the processing vessel 10. The deposition shield 52 may be provided on the inner wall of the processing vessel 10 and on an outer periphery of the stage 11.

An exhaust path 14 is formed between the inner wall of the processing vessel 10 and the stage 11. A baffle plate 15 of a conical shape (having a shape of a truncated cone) is provided at a position below the wafer W above the exhaust path 14. The baffle plate 15 is fixed to a member 53 disposed around the outer periphery of the stage 11. The baffle plate 15 regulates a flow of a gas, and prevents plasma from entering a space in the exhaust path 14.

A part of the processing space U can be opened and closed by a shutter 51. The shutter 51 moves up and down by driving a lifter 50 connected to the shutter 51, to open and close an opening (loading port 19) provided in the processing vessel 10.

An exhaust port 16 is formed at the bottom of the exhaust path 14. An exhaust device 18 is connected to the exhaust port 16 via an exhaust pipe 17. The exhaust device 18 includes a vacuum pump to reduce pressure in the processing space U in the processing vessel 10 to a predetermined quality of vacuum. The exhaust pipe 17 also includes an automatic pressure control valve (hereinafter referred to as an “APC”) which is a variable butterfly valve (not illustrated), and the APC automatically controls pressure in the processing vessel 10. In addition, a gate valve 20 is attached to a side wall of the processing vessel 10 to open and close the loading port 19 for the wafer W.

The gas showerhead 24 is supported to the ceiling of the processing vessel 10 via an insulating member 44. The gas showerhead 24 includes an electrode plate 37 and an electrode support 38 for detachably supporting the electrode plate 37. The electrode plate 37 has a large number of gas holes 37a. A buffer chamber 39 is formed within the electrode support 38. The process gas supply unit 40 is connected to a gas inlet 38a via a gas supply line 41. A gas supplied from the process gas supply unit 40 is introduced into the buffer chamber 39, and is supplied, through the large number of gas holes 37a, into the processing vessel 10.

Each component of the substrate processing apparatus 1 is coupled with the controller 43. The controller 43 controls each of the components of the substrate processing apparatus 1. Examples of the components include the exhaust device 18, the first radio frequency power supply 21, the second radio frequency power supply 22, the switch 27, the DC power supply 26, the chiller unit 32, the heat transmitting gas supply unit 35, and the process gas supply unit 40.

The controller 43 includes a CPU 43a and a memory 43b (memory device), and controls plasma processing in the substrate processing apparatus 1 by the CPU 43a reading out and executing a program and a process recipe stored in the memory 43b. The controller 43 controls opening and closing processes of the shutter 51, an electrostatic attracting process for attracting the edge ring 30 electrostatically, and a heat transmitting gas supplying process for supplying the heat transmitting gas, in accordance with the plasma processing.

An annular or concentric magnet 42 is disposed around the processing vessel 10. Inside the processing vessel 10 of the substrate processing apparatus 1, a unidirectional horizontal magnetic field is formed by the magnet 42. Also, an RF electric field in a vertical direction is formed by the radio frequency power applied between the stage 11 and the gas showerhead 24. This causes a magnetron discharge through a process gas in the processing vessel 10, and generates, near the surface of the stage 11, a high density plasma from the process gas.

In plasma processing, the substrate processing apparatus 1 first loads a wafer W through the loading port 19 while the gate valve 20 is in the open state, and place the wafer W on the stage 11. The exhaust device 18 evacuates the processing vessel 10. The process gas supply unit 40 introduces a process gas into the processing vessel 10. The heat transmitting gas supply unit 35 supplies a heat transmitting gas to the back surface of the wafer W. When the first radio frequency power supply 21 applies radio frequency power for plasma generation to the stage 11, the process gas is formed into a plasma, and a predetermined plasma process is applied to an upper surface of the wafer W by means of radicals or ions in the plasma. Also, radio frequency power for attracting ion may be applied to the stage 11 from the second radio frequency power supply 22.

[Structure of Baffle Plate and Shutter]

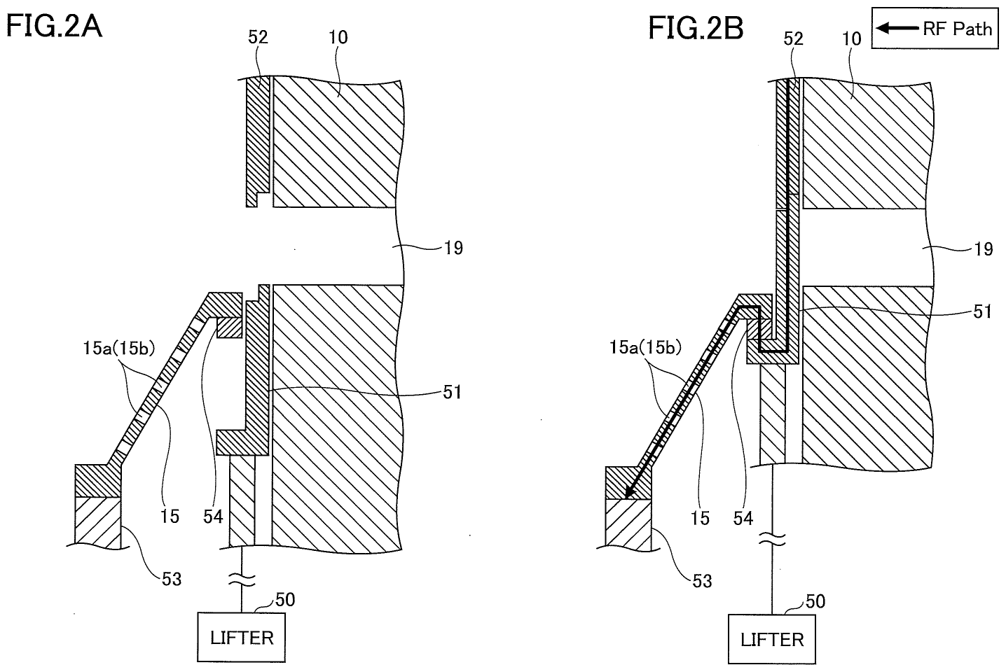

Next, structure of the baffle plate 15, the shutter 51, and their surroundings will be described with reference to FIG. 1 and FIGS. 2A and 2B. FIGS. 2A and 2B are enlarged views each illustrating an example of the baffle plate 15, the shutter 51, and their surroundings according to the present embodiment.

Referring to FIG. 1, the baffle plate 15 of a conical shape is provided between the deposition shield 52 and the stage 11. An opening of the top of the baffle plate 15 is larger than an opening of the bottom of the baffle plate 15.

At a part of an outer periphery of an upper end of the baffle plate 15, the shutter 51 is provided at a position corresponding to the loading port 19 such that the shutter 51 can move up and down. In a cross sectional view viewed from an axial direction of a central axis of the processing vessel 10, the shutter 51 is formed in a circular arc shape along a shape of an inner circumference of the processing vessel 10. As the shutter 51 is lifted, the shutter 51 contacts the deposition shield 52, thereby closing the loading port 19. At the lower end of the baffle plate 15, a member 53 is disposed around the outer periphery of the stage 11. The baffle plate 15 is fixed to the bottom of the processing vessel 10 via the member 53. As the member 53 is made of a conductive material, the baffle plate 15 is electrically connected to the processing vessel 10. The baffle plate 15 is an example of a first member that forms a ground plane (a region at a ground potential) with the processing vessel 10, with respect to the radio frequency power (radio frequency current) output from the first radio frequency power supply 21 and/or the second radio frequency power supply 22. As illustrated in an enlarged drawing in FIG. 2A or 2B, the upper end of the baffle plate 15 is bonded to a contact member 54 that is made of metal or ceramic-coated metal.

The baffle plate 15, the shutter 51, the deposition shield 52, and the member 53 are made of metal such as aluminum. The baffle plate 15, the shutter 51, the deposition shield 52, and the member 53 may be formed of an aluminum material coated with ceramic such as alumina or yttria (Y₂O₃).

A part of the processing space U (see FIG. 1) can be opened and closed by the shutter 51. At a time of loading and unloading a wafer W, as illustrated in FIG. 2A, the shutter 51 is lowered by driving the lifter 50 connected to the shutter 51, to open the shutter 51. In this state, the gate valve 20 is opened, a transfer arm (not illustrated) is inserted into the processing vessel 10 from the loading port 19, and the wafer W is loaded or unloaded.

During plasma processing, as illustrated in FIG. 2B, the shutter 51 is raised by driving the lifter 50, until the shutter 51 contacts the contact member 54 attached to the deposition shield 52, closing the shutter 51.

The deposition shield 52 is another example of the first member that contacts the processing vessel 10 and that forms a ground plane with respect to the radio frequency power output from the first radio frequency power supply 21 and/or the second radio frequency power supply 22, with the processing vessel 10.

The shutter 51 is an example of a second member that forms a ground plane with respect to the radio frequency power output from the first radio frequency power supply 21 and/or the second radio frequency power supply 22. The shutter 51 may also function as the first member that forms a ground plane with respect to the radio frequency power output from the first radio frequency power supply 21 and/or the second radio frequency power supply 22, with the processing vessel 10.

At least one of the shutter 51, the loading port 19, the gate valve 20, the exhaust path 14, the exhaust port 16, and the exhaust pipe 17 is an example of a particular structure within the processing vessel 10.

As illustrated in FIG. 2B, when the shutter 51 is closed, the shutter 51 is electrically connected to the baffle plate 15 and the deposition shield 52, to form a ground plane. That is, the processing vessel 10, the deposition shield 52, the shutter 51, and the baffle plate 15 become at a ground potential, which allow a plasma to be confined to the processing space U. With such a configuration, the processing space U becomes a plasma-generating space formed of the stage 11, the processing vessel 10, the gas showerhead 24, the baffle plate 15, the shutter 51, and the deposition shield 52.

In a case in which the exhaust port 16 at the bottom of the processing vessel 10 is disposed at a biased position, exhaust gas flow is biased. The baffle plate 15 has a function to improve the flow of the exhaust gas in a circumferential direction by causing the gas to pass through through-holes 15a and 15b, thereby eliminating deviation of the exhaust gas. The baffle plate 15 also has a function of separating the exhaust path 14 from the processing space U, to prevent a plasma from entering the exhaust path 14.

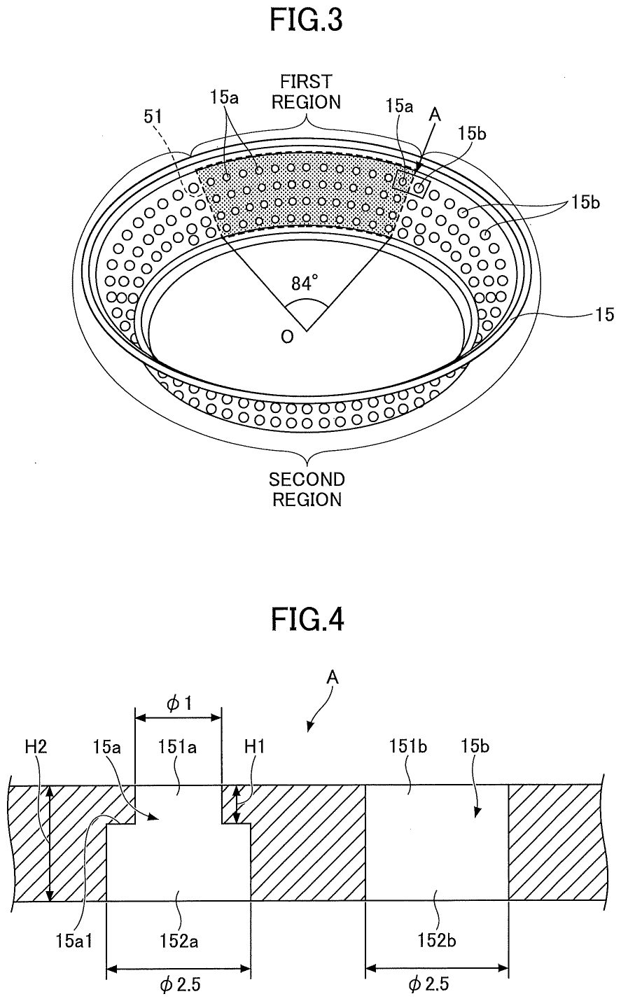

As illustrated in FIG. 3, in the baffle plate 15, the multiple through-holes 15a and 15b that penetrate the baffle plate 15 are arranged uniformly in the circumferential direction. The multiple through-holes 15a and 15b penetrate perpendicularly with respect to the top and bottom surfaces of the baffle plate 15.

In the present embodiment, the baffle plate 15 is of a conical shape, but may be formed in a shape of a flat annular ring. However, by forming the baffle plate 15 into a conical shape, because the number of the through-holes 15a and 15b can be increased, the above-described function can be improved. In addition, a surface area of the baffle plate 15 can also be increased.

Referring back to FIG. 2B, when the shutter 51 is closed during the plasma processing, the baffle plate 15, the shutter 51, and the deposition shield 52 are electrically connected. Thus, the baffle plate 15, the shutter 51, and the deposition shield 52 become a ground potential, and form a path through which current of a radio frequency (RF current) that is output from the first radio frequency power supply 21 and/or the second radio frequency power supply 22 flows. Hereinafter, the path through which the RF current flows is also referred to as a radio frequency path (RF path).

In the state of FIG. 2B, the shutter 51 and the deposition shield 52 are electrically connected (in contact via the contact member 54). However, a region with which the shutter 51, the deposition shield 52, and the shutter 51 are in contact may become electrically unstable, and conductivity of the RF current is likely to degrade.

In the following description, a center of the bottom surface of the annular baffle plate 15 illustrated in FIG. 3 is referred to as a point “O”. The center of the bottom surface of the baffle plate 15 is substantially the same as the center of the processing vessel 10. An area of the baffle plate 15 within an angle of 84° seen from the point O, which contacts the shutter 51 when the shutter 51 is closed and which is separated from the shutter 51 when the shutter 51 is opened, is referred to as a “first region”, and a residual area of the baffle plate 15, which is an area within an angle of 276° (=360°-84°) seen from the point O, is referred to as a “second region”. The second region does not contact the shutter 51 even if the shutter 51 is closed.

Because the first region is not permanently connected to the shutter 51 via the contact member 54, if the first and second regions have the same impedance, electrical conductance of a path of the RF current passing through the first region and the processing vessel 10 via the shutter 51 tends to be lower than that of another path of the RF current passing through the second region and the processing vessel 10 without passing through the shutter 51. Note that, in the following description, the above-mentioned path of the RF current passing through the first region and the processing vessel 10 via the shutter 51 may also be referred to as a “first path”, and the another path of the RF current passing through the second region and the processing vessel 10 without passing through the shutter 51 may also be referred to as a “second path”.

Therefore, when a plasma etching process is applied to a wafer W, CD (Critical Dimension) of a hole formed at a side of the wafer W where the shutter 51 is disposed tends to differ from CD of a hole formed at the other side of the wafer W where the shutter 51 is not provided. To avoid occurrence of the above-mentioned tendency, the baffle plate 15 according to the present embodiment is configured such that, with respect to the RF current, electrical conductance of the first region, which is configured to contact the shutter 51 when the shutter 51 is closed, is higher than that of the second region that is not in contact with the shutter 51. This can equalize electrical conductance (or impedance) between the first path and the second path. As the above-described configuration can eliminate differences between CD of a hole formed on a side of the wafer W where the shutter 51 is provided and CD of a hole formed on the other side of the wafer W where the shutter 51 is not present, process characteristics and productivity are improved.

A configuration for adjusting the impedance (or electrical conductance) of the baffle plate 15 will be described with reference to FIGS. 3 and 4. As illustrated in FIG. 3, the diameter of the through-hole 15a in the first region is smaller than the diameter of the through-hole 15b in the second region on a surface (upper surface) of the baffle plate 15 that is exposed to the plasma. FIG. 4 is an enlarged view of the through-holes 15a and 15b in a region “A” of FIG. 3. FIG. 4 illustrates a cross-sectional view of the region “A” of FIG. 3. The diameter (ϕ1) of the opening 151a of the through-hole 15a formed on the upper surface of the baffle plate 15 is formed to be less than half the diameter (φ2.5) of the opening 151b of the through-hole 15b formed on the upper surface of the baffle plate 15. However, the ratio of the size of the opening 151a to the size of the opening 151b is not limited to this as long as the opening 151a is formed to be smaller than the opening 151b.

Meanwhile, the diameter (φ2.5) of the through-hole 152a formed on the lower surface of the baffle plate 15 is the same as the diameter (φ2.5) of the through-hole 152b formed on the lower surface of the baffle plate 15. Further, in a case in which a thickness of the baffle plate 15 is H2, a step 15al is formed at a depth of H1 (H1<H2) from the upper surface of the baffle plate 15.

The above-described structure allows a surface area per unit volume of the upper surface of the first region of the baffle plate 15 and of the inner wall surface of the through-hole 15a to be greater than a surface area per unit volume of the upper surface of the second region and the inner surface of the through-hole 15b. This causes impedance of the first region of the baffle plate 15 with respect to the RF current supplied from the first radio frequency power supply 21 and/or the second radio frequency power supply 22 to be lower than the impedance of the second region of the baffle plate 15 with respect to the RF current supplied from the first radio frequency power supply 21 and/or the second radio frequency power supply 22.

By increasing the surface area per unit volume of the first region of the baffle plate 15 to be larger than the surface area per unit volume of the second region, the impedance of the first region of the baffle plate 15 can be made to be lower than the impedance of the second region of the baffle plate 15. Thus, even if impedance of an area near the baffle plate 15 that is configured to contact the shutter 51 becomes high, a path of the RF current passing through the shutter 51 (the above-mentioned first path) and a path of the RF current not passing through the shutter 51 (the above-mentioned second path) can be adjusted to have substantially the same electrical conductance (impedance) with respect to the RF current. This can eliminate differences between CD of a hole formed on a side of the wafer W where the shutter 51 is present and CD of a hole formed on the other side of the wafer W where the shutter 51 is not present, thereby improving process characteristics and productivity.

Further, as the step 15a1 is formed in the through-hole 15a in the first region of the baffle plate 15 to widen the opening on the lower surface of the baffle plate 15, conductance of a gas passing through the through-hole 15a can be secured. Therefore, it is possible to secure both equalization in impedance of RF current propagation paths and equalization in gas conductance.

As described above, the substrate processing apparatus 1 according to the present embodiment includes the processing vessel 10, the radio frequency power supply 21, the radio frequency power supply 22, and the member forming a ground plane with the processing vessel 10 with respect to the radio frequency power output from the radio frequency power supplies 21 and 22. The member is configured such that a surface area per unit volume of a first region of the member corresponding to a particular structure of the processing vessel 10 differs from a surface area per unit volume of a second region of the member other than the first region to adjust impedance (or electrical conductance) with respect to radio frequency current output from the radio frequency power supplies 21 and 22. This allows the impedance in the member forming the ground plane with respect to the radio frequency power to be adjusted. This can eliminate differences between CD of a hole formed on a side of a wafer where the particular structure is present and CD of a hole formed on the other side of the wafer where the particular structure is not present, thereby improving process characteristics and productivity. The member may be any one of the baffle plate 15, the shutter 51, and the deposition shield 52. The particular structure may be a shutter.

[Variations]

The surface area per unit volume of the first region of the member and the surface area per unit volume of the second region of the member may be determined based on a region in the processing vessel 10 in which the particular structure of the processing vessel 10 is present and a region in the processing vessel 10 in which the particular structure is not present. For example, in a cross-sectional view seen from an axial direction of a central axis of the processing vessel 10, let a central angle of the particular structure (an angle whose vertex is a center of the processing vessel 10 in the cross-sectional view) be “x”, which is formed by a line originating from the center of the processing vessel 10 to an end of the particular structure and by a line originating from the center of the processing vessel 10 to another end of the particular structure. In this case, the member may be configured such that the surface area per unit volume of the first region and the surface area per unit volume of the second region are determined based on a ratio of the central angle x of the particular structure to a conjugate angle (360°-x) of the central angle x. A specific example will be described with reference to FIG. 3.

In FIG. 3, the shutter 51 (an example of the particular structure) is provided along an outer circumference of the first region of the baffle plate 15, in a form of a circular arc having a central angle of 84°. In such a case, in the cross-sectional view seen from the axial direction of the central axis of the processing vessel 10, the surface area per unit volume of the first region and the surface area per unit volume of the second region may be determined based on a ratio of a central angle of the shutter 51 (the circular arc) having the central angle of 84° (a region in which the shutter 51 is present) to a central angle of a region (circular arc) having the conjugate angle of 84° (i.e. 360°-84°=276).

In the above-described embodiment, in order to adjust the impedance (or electrical conductance) of the first region and the second region, a shape of the hole formed in the first region is caused to differ from a shape of the hole formed in the second region such that a surface area per unit volume of the first region differs from a surface area per unit volume of the second region. However, a method of adjusting the impedance (or electrical conductance) is not limited thereto. For example, in order to adjust the impedance (or electrical conductance) of the first region and the second region, the number of holes per unit area of the first region may be made to differ from the number of holes per unit area of the second region such that a surface area per unit volume of the first region differs from a surface area per unit volume of the second region.

In the above-described embodiment, the shutter 51 is used as an example of the particular structure of the processing vessel 10 that causes non-uniformity in impedance. However, non-uniformity in impedance may occur in multiple locations. If more than one shutter 51 is provided, non-uniformity in impedance occurs in two locations. Accordingly, in this case, the impedance may be adjusted by changing the shape of the through-hole 15a of the first region, which is the two regions corresponding to the two shutters, and the through-hole 15b of the second region, which is the other region than the first region.

In the above-described embodiment, by causing the shape of the through-hole 15a in the first region to differ from the shape of the through-hole 15b in the second region, the surface area per unit volume of the first region of the baffle plate 15 is made to be larger than the surface area per unit volume of the second region of the baffle plate 15. However, a method of making the surface area per unit volume of the first region of the baffle plate 15 differ from the surface area per unit volume of the second region of the baffle plate 15 is not limited thereto. For example, the surface area per unit volume of the first region of the baffle plate 15 may be made to be larger than the surface area per unit volume of the second region of the baffle plate 15 by making a shape of the surface of the first region of the baffle plate 15 differ from a shape of the surface of the second region of the baffle plate 15. Alternatively, the surface area per unit volume of the first region of the baffle plate 15 may be made to be larger than the surface area per unit volume of the second region of the baffle plate 15 by making a thickness of the first region of the baffle plate 15 differ from a thickness of the second region of the baffle plate 15.

In addition, the impedance may be adjusted by applying surface treatment on the first region of the baffle plate 15, such as forming of a thermal spray film of yttrium oxide or alumina. By forming an insulating film on the surface of the first region using thermal spraying or other coating techniques, the impedance of the first region can be made to be higher than the impedance of the second region. This improves a state in which the impedance of the first region on the shutter 51 is reduced excessively by making the surface area per unit volume of the first region too large compared to the surface area per unit volume of the second region, and can equalize impedance (or electrical conductance) between a path (first path) of the RF current passing through the first region of the baffle plate 15 and a path (second path) of the RF current passing through the second region of the baffle plate 15.

The substrate processing apparatus according to the embodiment disclosed herein should be considered exemplary in all respects and not limiting. The above-described embodiment and its variations may be modified and enhanced in various forms without departing from the appended claims and spirit thereof. Matters described in the above-described embodiment and its variations may take other configurations to an extent not inconsistent, and may be combined to an extent not inconsistent.

The substrate processing apparatus according to the present disclosure is applicable to any type of substrate processing apparatus, including an atomic layer deposition (ALD) apparatus, a capacitively coupled plasma (CCP) type processing apparatus, an inductively coupled plasma (ICP) type processing apparatus, a processing apparatus using a radial line slot antenna (RLSA), an electron cyclotron resonance plasma (ECR) type processing apparatus, and a helicon wave plasma (HWP) type processing apparatus.

What is claimed is:

1. A substrate processing apparatus comprising:
a processing vessel;
a radio frequency power supply configured to supply radio frequency (RF) current; and
a member electrically connected to the processing vessel, the member being configured such that a surface area per unit volume of a first region of the member corresponding to a particular structure of the processing vessel differs from a surface area per unit volume of a second region of the member other than the first region, in order to adjust impedance of the member.

2. The substrate processing apparatus according to claim 1, wherein the surface area per unit volume of the first region of the member and the surface area per unit volume of the second region are determined based on a central angle of the particular structure and a conjugate angle of the central angle of the particular structure in a cross-sectional view seen from an axial direction of a central axis of the processing vessel, the central angle being formed by a line from a center of the processing vessel to an end of the particular structure and by a line from the center of the processing vessel to another end of the particular structure.

3. The substrate processing apparatus according to claim 1, wherein the surface area per unit volume of the first region of the member is configured to differ from the surface area per unit volume of the second region of the member, by causing a shape of a hole formed in the first region of the member to differ from a shape of a hole formed in the second region of the member, or by causing a number of holes per unit area of the first region of the member to differ from a number of holes per unit area of the second region of the member.

4. The substrate processing apparatus according to claim 1, wherein the member is a baffle plate.

5. The substrate processing apparatus according to claim 4, wherein
the baffle plate includes a hole in the first region; and
a diameter of the hole on a lower surface of the baffle plate is larger than a diameter of the hole on an upper surface of the baffle plate.

6. The substrate processing apparatus according to claim 4, wherein the baffle plate is of a conical shape.

7. The substrate processing apparatus according to claim 2, wherein the particular structure is a shutter.

8. The substrate processing apparatus according to claim 7, wherein
the member is a baffle plate that is electrically connected to the processing vessel;
the shutter is configured to contact the first region of the baffle plate and the processing vessel when the shutter is closed, and to be separate from the first region of the baffle plate when the shutter is opened; and
the baffle plate is configured such that impedance of a first path of the RF current passing through the processing vessel and the first region of the baffle plate via the shutter is substantially equal to impedance of a second path of the RF current passing through the processing vessel and the second region of the baffle plate and not passing through the shutter.
